(19) United States
(12) Patent Application Publication
(10) Pub. No.: US 2021/0263572 A1
(43) Pub. Date: Aug. 26, 2021

(54) SLIDE IN EQUIPMENT RACK WITH POWER DISTRIBUTION UNIT ALLOWING CORDLESS POWERING OF DEVICES

(71) Applicant: Murat Yildirim, Aurora, CO (US)

(72) Inventor: Murat Yildirim, Aurora, CO (US)

(21) Appl. No.: 17/215,283

(22) Filed: Mar. 29, 2021

(51) Int. Cl. G06F 1/18; H05K 7/18

(52) U.S. Cl. CPC G06F 1/188; H05K 7/183; G06F 1/189

(57) ABSTRACT

The present invention relates to a modular rack with screwless mountable power distribution unit (PDU) for use in distributing power within an equipment cabinet or rack, such as a computer equipment rack or a data storage cabinet. An aspect of the present invention relates to a power distribution system for distributing power to electrical or computer equipment. The power distribution system includes a rack body for holding a plurality of rack-mounted computing assets therein, the rack body having a top portion, a bottom portion, and a plurality of mounting rails that connect vertically said top portion to said bottom portion, and the plurality of rack-mounted computing assets at least has one or more power distribution units (PDUs) for providing electrical power to a plurality of computing assets. Each of the plurality of mounting rails being formed with a receiving groove, and the PDUs are configured to be oriented horizontally in the rack and configured to be secured among said mounting rails using mounting brackets without any screws.

### TECHNICAL FIELD

The present invention relates generally to screwless mountable network equipment within an equipment cabinet or network rack also known as server rack and cordless powering of installed devices with attached power distribution unit.

### BACKGROUND

A power distribution unit (PDU) is a device fitted with multiple outputs designed to distribute electric power, especially to racks of computers and networking equipment located within a telecommunication room, network room and/or data center. PDUs vary from simple and inexpensive rack-mounted power strips to larger floor-mounted PDUs with multiple functions including power filtering to improve power quality, intelligent load balancing, and remote monitoring and control by LAN or SNMP.

Power distribution units (PDUs) are typically used to provide power to multiple servers and other devices mounted on a rack. Conventionally, a rack includes two or four vertical rack posts with rectangular cross sections. Conventionally, a PDU is vertically mounted to the outside of one of the rack posts, causing the PDU to protrude from the rest of the rack. Alternatively, a PDU with the same shape as a rack-mounted server is mounted in the area between the posts of the rack.

However, mounting the PDU between the rack posts occupies space that could otherwise be used to house additional servers. Also, mourning of the PDU requires specialized technicians its the mounting needs conventional technics like screwing etc.

The invention is directed to overcoming one or more of the problems and solving one or more of the needs as set forth above.

### SUMMARY OF THE INVENTION

The present invention addresses the above discussed and additional problems by providing a modular power distribution system for use in distributing power to devices, modules, and/or enclosures mounted within equipment racks or cabinets.

Embodiments of the invention provide a power distribution unit (PDU) mounted within a rack structure. A mechanical interface secures the PDU within a portion of the rack structure. The PDU is connected so that it is configured to provide electrical power to computing assets mounted within the rack without using the power cords between attached devices and PDU. Securing the PDU within the rack structure allows placement of the PDU so it does not occupy space exterior to the rack or space enclosed by the rack (e.g., space between posts of the rack structure). This increases the space within the rack in which computing assets may be mounted.

An aspect of the present invention relates to a power distribution system for distributing power to electrical or computer equipment. The power distribution system includes a rack body for holding a plurality of rack-mounted computing assets therein, the rack body having a top portion, a bottom portion, and a plurality of mounting rails that connect vertically said top portion to said bottom portion, and the plurality of rack-mounted computing assets at least having one or more power distribution units (PDUs) for providing electrical power to a plurality of computing assets.

Each of the plurality of mounting rails being formed with a receiving groove, and the network devices are configured to be oriented horizontally in the rack and configured to be secured among said mounting rails using mounting brackets without any screws.

In an exemplary aspect, the PDUs are configured to be oriented vertically in the rack and configured to be secured among said mounting rails with receiving grooves without any screws.

In an exemplary aspect, each of the PDUs may include 45 C14 outlets and 12 Nema 15 outlets.

In an exemplary aspect, each of the PDUs may include at least one C14 outlets and at least one Nema 15 outlets.

In an exemplary aspect, the mounting brackets without any screws enable a quick mounting option on each of the Pals to be installed and uninstalled.

In an exemplary aspect, each of the PDUs having built in thermometer to measure room temperature.

In an exemplary aspect, each of the PDUs having a transceiver to receiver and/or transmit an associated current status to a remote device or a server.

In an exemplary aspect, each of the PDUs providing a web interface to remotely monitor the installed PDUs and to provide console access to configure the PDUs.

In an exemplary aspect, the system includes a plurality of high density bundled network cables having combinations of 8, 16, 32, 48, 64, 96 and 192 count wire bundles connected to one or more distribution blocks provided in the power distribution system.

In an exemplary aspect, the system includes at least wall jacks with digital screen face plates. In another exemplary aspect, the wall jacks include standard RJ45 wall jacks and USB Type C wall jacks. In another exemplary aspect, the USB Type C jacks may be placed inside the RJ45 jacks. In yet another exemplary aspect, the wall jacks include at least one of motion sensors, microphone and camera to communicate with at least one of a remote device or a server.

In an exemplary aspect, the mounting brackets include a latching mechanism integrated into at least one end of each of the PDUs.

In an exemplary aspect, at least one if the computing assets is a server.

Following elements forms the integral part of the invention. Various other elements which are novel are described below.

Head End Equipment

Components of a head end equipment's are, network rack, power distribution unit, patch panel, network switch and network switch/patch panel.

Network rack is designed to promote rack and stack efficiency while offering a resiliency. It meets EIA-ECA-310 standards and it provides additional functions to provide a more efficient way to install and deinstall devices.

PDU will have 45 C14 outlets and 12 Nema 15 outlets. Quick mourning option on the PDU will allow it to be installed and deinstalled without any screws. PDU will have built in thermometer to measure room temperature.

The web interface of the PDU will allow users to remotely see installed devices and provide console access to configure the equipment. Combination of this rack, PDU and network device offers an unmatched resiliency of a head and system.

Cabling and Distribution Blocks

Components of cabling are high density bundled network cables. Combinations of 8, 16, 32, 48, 64, 96 and 192 count wire bundles connected to distribution blocks will form the cabling part of the system.

Bundled cabling can also be used for led lightning. Separate bundled cabling to provide low volt electric to lights. Light switched will be integrated to smart home system where they will serve multiple purposes. While light switches turn tights on and off they also have built in sensors, microphone and camera to easily send comments to centralized smart home equipment.

Wall Jacks and Face Plates

This system will include 2-4 and 6 port wall jacks with digital screen face plates. Wall jacks will be hybrid solution of standard RJ45 wall jacks as well as USB Type C wall jacks. USB Type C jacks will be placed inside the RJ45 jacks.

Additionally wall jacks will include built in motion sensors, microphone and camera to send comments to smart home devices.

This pre-manufactured cabling system will reduce the installation time, minimize errors, offer future-proofing, help with labeling and documentation of wiring and provide visibility to network cabling infrastructure.

It is briefly noted that upon a reading this disclosure, those skilled in the art may recognize various means for carrying out these intended features of the invention. As such it is to be understood that other methods, applications and systems adapted to the task may be configured to carry out these features and are therefore considered to be within the scope and intent of the present invention, and are anticipated. With respect to the above description, before explaining at least one preferred embodiment of the herein disclosed invention in detail, it is to be understood that the invention is not limited in its application to the details of construction and to the arrangement of the components in the following description or illustrated in the drawings. The invention herein described is capable of other embodiments and of being practiced and carried out in various ways which may be obvious to those skilled in the art. Also, it is to be understood that the phraseology and terminology employed herein are for the purpose of description and should not be regarded as limiting.

As such, those skilled in the art may appreciate that the conception upon which this disclosure is based may readily be utilized as a basis for designing of other structures, methods and systems for carrying out the several purposes of the present disclosed device. It is important, therefore, that the claims be regarded as including such equivalent construction and methodology insofar as they do not depart from the spirit and scope of the present invention. As used in the claims to describe the various inventive aspects and embodiments, “comprising” means including, but not limited to, whatever follows the word “comprising”. Thus, use of the term “comprising” indicates that the listed elements are required or mandatory, but that other elements are optional and may or may not be present. By “consisting of” is meant including, and limited to, whatever follows the phrase “consisting of”. Thus, the phrase “consisting of” indicates that the listed elements are required or mandatory, and that no other elements may be present. By “consisting essentially of” is meant including any elements listed after the phrase, and limited to other elements that do not interfere with or contribute to the activity or action specified in the disclosure for the listed elements. Thus, the phrase “consisting essentially of” indicates that the listed elements are required or mandatory, but that other elements are optional and may or may not be present depending upon whether or not they affect the activity or action of the listed elements.

The objects features, and advantages of the present invention, as well as the advantages thereof over existing prior art, which may become apparent from the description to follow, are accomplished by the improvements described in this specification and hereinafter described in the following detailed description which fully discloses the invention, but should not be considered as placing limitations thereon.

The summary of the invention does not necessarily disclose all the features essential for defining the invention. The invention may reside in a sub-combination of the disclosed features. The various combination and sub-combination are fully described in the detailed description.

### BRIEF DESCRIPTION OF DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

The diagrams are for illustration only, which thus is not a limitation of the present disclosure, and wherein:

FIG. 1 is a side view of a power distribution system showing a rack and the PDU to be mounted thereon, according to one embodiment suitable for practicing the invention.

FIG. 2 shows a mounting mechanism of the PDU during mounting on the rack in accordance with a working example of an embodiment of the invention.

FIGS. 3A-3B shows a latching and locking mechanism of the network device during mounting on the rack in accordance with a working example of an embodiment of the invention.

### DETAILED DESCRIPTION OF DRAWINGS

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure.

In the following description, numerous specific details are set forth in order to provide a thorough understanding of embodiments of the present invention. It may be apparent to one skilled in the art that embodiments of the present invention may be practiced without some of these specific details.

Various terms as used herein are shown below. To the extent a term used, it should be given the broadest definition persons its the pertinent art have given that term as reflected in printed publications and issued patents at the time of filing.

In an embodiment of the present invention the computer networking product line as proposed in the present invention may simplify the physical and logical networking. End to end system may consist of 3 major categories viz., head end equipment, cabling and distribution blocks, and wall jacks and face plates.

In an exemplary embodiment, the components of head end equipments are, network rack, power distribution unit (PDU), patch panel, network switch and network switch/patch panel.

In an exemplary embodiment, the network rack is designed to promote rack and stack efficiency while offering a resiliency. It meets EIA-ECA-310 standards and it provides additional functions to provide a more efficient way to install and uninstall devices.

In an exemplary embodiment, the power distribution unit (PDU) may have 45 C14 outlets and 12 Nema 15 outlets. Quick mounting option on the PDU may allow it to be installed and uninstalled without any screws. PDU may have built in thermometer to measure room temperature.

In an exemplary embodiment, a web interface of the PDU may allow users to remotely see installed devices and provide console access to configure the equipment.

In an exemplary embodiment, the combination of this rack, PDU and network device offers an unmatched resiliency of a head and system.

In an exemplary embodiment, components of the cabling are high density bundled network cables. Combinations of 8, 16, 32, 48, 64, 96 and 192 count wire bundles connected to distribution blocks will form the cabling part of the system.

In another exemplary embodiment, Bundled cabling can also be used for led lightning. Separate bundled cabling to provide low volt electric to lights. Light switched will be integrated to smart home system where they will serve multiple purposes. While light switches turn lights on and off, they will also have built in sensors, microphone and camera to easily send comments to centralized smart home equipment.

In an exemplary embodiment, the system will include 2-4 and 6 port wall jacks with digital screen thee plates. Wall jacks will be hybrid solution of standard RJ45 wall jacks as well as USB Type C wall jacks. USB Type C jacks will be placed inside the RJ45 jacks. Additionally wall jacks will include built in motion sensors, microphone and camera to send comments to smart home devices.

In exemplary embodiment, this pre-manufactured cabling system will reduce the installation time, minimize errors, offer future-proofing, help with labeling and documentation of wiring and provide visibility to network cabling infrastructure.

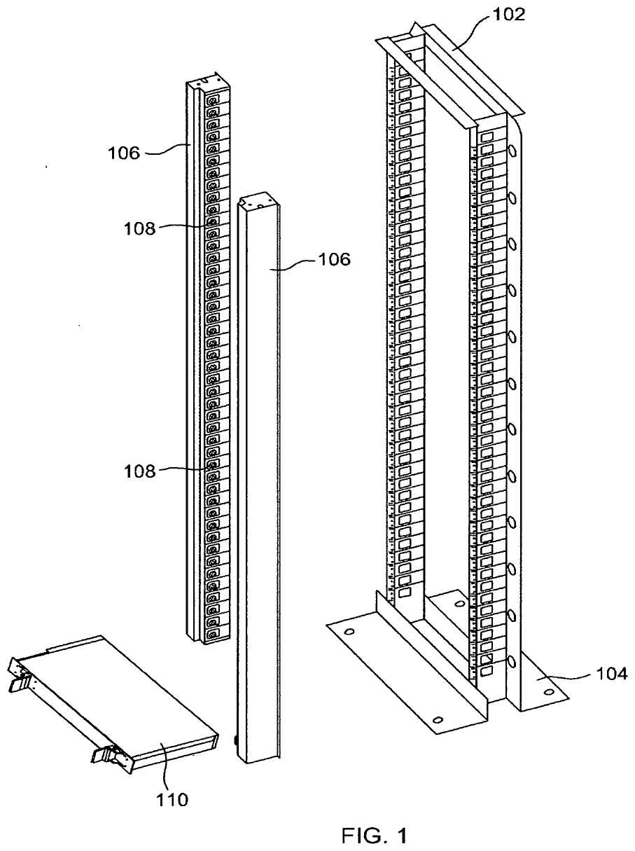

FIG. 1 is illustrate a side view of a power distribution system showing a rack, a network device and the PDU to be mounted thereon, according to one embodiment suitable for practicing the invention.

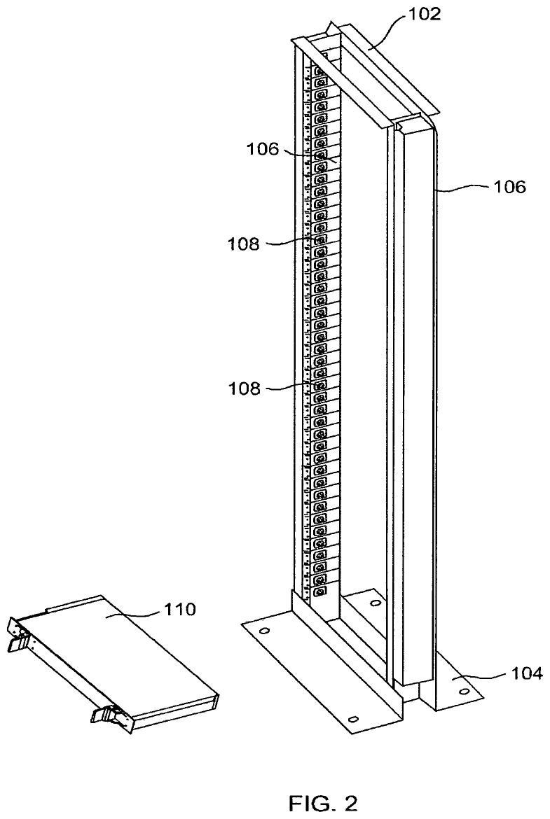

FIG. 2 illustrates a mounting mechanism of the PDU during mounting on the rack in accordance a working example of an embodiment of the invention.

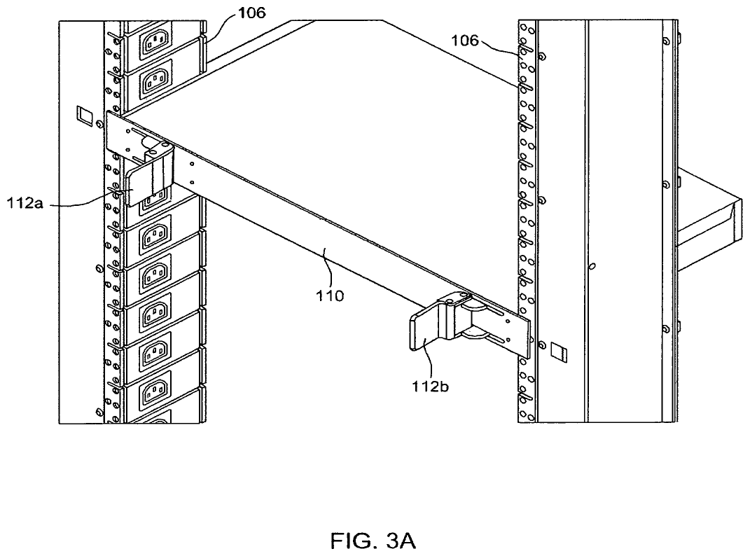

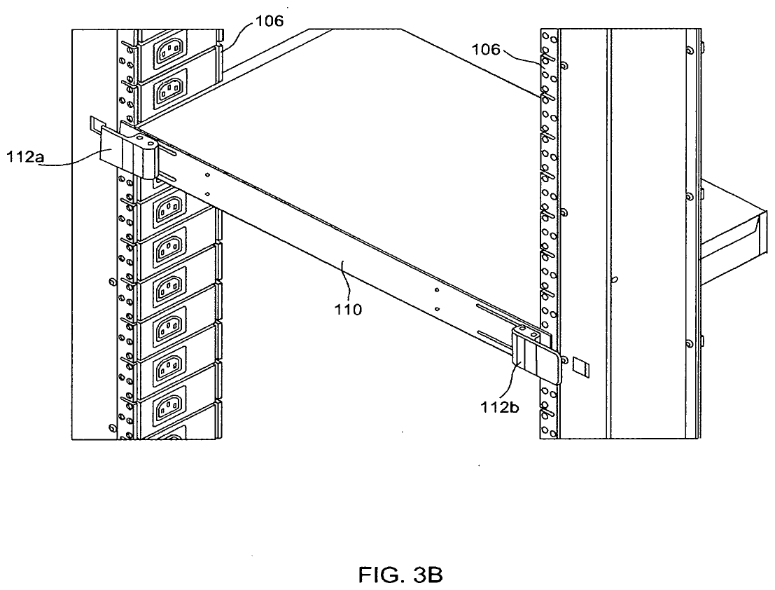

FIGS. 3A-3B shows a latching and locking mechanism of the network device during mounting on the rack in accordance with a working example of an embodiment of the invention.

FIG. 3A shows the mounting brackets 112a and 112b in open or unlocked position and FIG. 3B shows the mounting brackets 112a and 112b in closed or locked position.

In an embodiment, a power distribution system for distributing power to electrical or computer equipment. The power distribution system includes a rack body for holding a plurality of rack-mounted computing assets therein, the rack body having plurality of slots or grooves, a top portion (102), a bottom portion (104), and a plurality of mounting rails (106) that connect vertically said top portion to said bottom portion (104), and the plurality of rack-mounted computing assets at least having one or more power distribution units (PDUs) (108) for providing electrical power to a plurality of computing assets.

Each of the plurality of mounting rails (106) being formed with a receiving electrical grooves, the PDUs and a network device (110) are configured to be oriented horizontally in the nick and configured to be secured among said mounting rails using mounting brackets (112a, 112b) without any screws.

In an exemplary embodiment, the network devices are configured to be oriented horizontally in the rack and configured to be secured among said mounting rails using mounting brackets (112a, 112b) without any screws.

In an exemplary embodiment, each of the PDUs may include 45 C14 outlets and 12 Nema 15 outlets.

In an exemplary embodiment, each of the PDUs may include at least one C14 outlets and at least one Nema 15 outlets.

In an exemplary embodiment, the mounting brackets (112a, 112b) without any screws enable a quick mounting option on each of the network devices to be installed and uninstalled.

In an exemplary embodiment, each of the PDUs having built in thermometer to measure room temperature.

In an exemplary embodiment, each of the PDUs having a transceiver to receiver and/or transmit an associated current status to a remote device or a server.

In an exemplary embodiment, each of the PDUs providing a web interface to remotely monitor the installed PDUs and to provide console access to configure the PDUs.

In an exemplary embodiment, the system includes a plurality of high density bundled network cables having combinations of 8, 16, 32, 48, 64, 96 and 192 count wire bundles connected to one or more distribution blocks provided in the power distribution system.

In an exemplary embodiment, the system includes at least will jacks with digital screen face plates. In another exemplary aspect, the wall jacks include standard RJ45 wall jacks and USB Type C wall jacks. In another exemplary aspect, the USB Type C jacks may be placed inside the RJ45 jacks. In yet another exemplary aspect, the wall jacks include at least one of motion sensors, microphone and camera to communicate with at least one of a remote device or a server.

In an exemplary embodiment, the mounting brackets include a latching mechanism integrated into at least one end of each of the network devices.

In an exemplary embodiment, at least one of the computing assets is a server.

Where applicable, various embodiments provided by the present disclosure may be implemented using hardware, software, or combinations of hardware and software. Also, where applicable, the various hardware components and/or software components set forth herein may be combined into composite components comprising software, hardware, and/or both without departing from the spirit of the present disclosure. Where applicable, the various hardware components and/or software components set forth herein may be separated into sub-components comprising software, hardware, or both without departing from the scope of the present disclosure. In addition, where applicable, it is contemplated that software components may be implemented as hardware components and vice-versa.

Software in accordance with the present disclosure, such as program code and/or data, may be stored on one or more computer readable mediums. It is also contemplated that software identified herein may be implemented using one or more general purpose or specific purpose computers and/or computer systems, networked and/or otherwise. Where applicable, the ordering of various steps described herein may be changed, combined into composite steps, and/or separated into sub-steps to provide features described herein

The various features and steps described herein may be implemented as systems comprising one or more memories storing various information described herein and one or more processors coupled to the one or more memories and a network, wherein the one or more processors are operable to perform steps as described herein, as non-transitory Machine-readable medium comprising a plurality of machine-readable instructions which, when executed by one or more processors, are adapted to cause the one or more processors to perform a method comprising steps described herein, and methods performed by one or more devices, such as a hardware processor, user device, server, and other devices described herein.

What is claimed is:

1. A power distribution system for distributing power to electrical or computer equipment comprising:
a rack body for holding a plurality of rack-mounted computing assets therein, the rack both having a top portion a bottom portion, and a plurality of mounting rails that connect vertically said top portion to said bottom portion, each of the plurality amounting rails being formed with a receiving groove; and
the plurality of rack-mounted computing assets at least having one or more power distribution units (PDUs) for providing electrical power to a plurality of computing assets, the PDUs are configured to be oriented horizontally in the rack and configured to be secured among said mounting rails using mounting brackets without any screws.

2. The power distribution system of claim 1, wherein the mounting brackets having snap shut or snapped shut mechanism for mounting the PDUs is on said mounting rails.

3. The power distribution system of claim 1, wherein each of the PDUs having 45 C14 outlets and 12 Nema 15 outlets.

4. The power distribution system of claim 1, wherein each of the PDUs having at least one C14 outlets and at least one Nema 15 outlets.

5. The power distribution system of claim 1, wherein the mounting brackets without any screws enables a quick mounting option on each of the PDUs to be installed and uninstalled.

6. The power distribution system of claim 1, wherein each of the PDUs having built in thermometer to measure temperature.

7. The power distribution system of claim 1, wherein each of the PDUs having a transceiver to receiver and/or transmit an associated current status to a remote device or server.

8. The power distribution system of claim 1, wherein each of the PDUs providing a web interface to remotely monitor the installed PDUs and to provide console access to configure the PDUs.

9. The power distribution system of claim 1, comprises a plurality of high density bundled network cables having combinations of 8, 16, 32, 48, 64, 96 and 192 count wire bundles connected to one or more distribution blocks provided in the power distribution system.

10. The power distribution system of claim 1, comprises at least wall jacks with digital screen face plates.

11. The power distribution system of claim 10, wherein the wall jacks include standard RJ45 wall jacks and USB Type C wall jacks.

12. The power distribution system of claim 11, wherein the USB Type C jacks will be placed inside the RJ45 jacks.

13. The power distribution system of claim 10, wherein the wall jacks include at least one of motion sensors, microphone and camera to communicate with at least one of a remote device or a server.

14. The power distribution system of claim 1, wherein the mounting brackets comprises a latching mechanism integrated into at least one end of each of the PDUs.

15. The power distribution system of claim wherein at least one of the computing assets is a server or a network device.
